(19) United States
(12) Patent Application Publication
(10) Pub. No.: US 2008/0237702 A1
(43) Pub. Date: Oct. 2, 2008

(54) LDMOS TRANSISTOR AND METHOD OF MAKING THE SAME

(76) Inventors: Chih-Hua Lee, Hsinchu City (TW); Chien-Wei Li, Hsinchu City (TW)

Correspondence Address: NORTH AMERICA INTELLECTUAL PROPERTY CORPORATION, P.O. BOX 506, MERRIFIELD, VA, 22116, US

(21) Appl. No.: 11/691,489

(22) Filed: Mar. 26, 2007

(51) Int. Cl. H01L 29/76

(52) U.S. Cl. 257/336

(57) ABSTRACT

An LDMOS transistor includes a substrate having first conductive type, a first well having second conductive type, an isolation structure disposed on the substrate, and a deep doped region having first conductive type disposed between the first well and the substrate. The deep doped region is heavily doped, a portion of the deep doped region is disposed in the bottom portion of the first well, and the other portion of the deep doped region is disposed in the substrate.

### BACKGROUND OF THE INVENTION

1. Field of the Invention

The present invention relates to a lateral diffused metal oxide semiconductor (LDMOS) transistor and method of making the same, and more particularly, to an LDMOS transistor having high breakdown voltage and high voltage step-down ability and method of making the same.

2. Description of the Prior Art

LDMOS transistor is mainly applied to high voltage integrated circuits. Generally, the operational voltage of LDMOS is ranging from 20 to 300 V, and thus it requires high breakdown voltage.

Please refer to FIG. 1. FIG. 1 is a cross-sectional view of a conventional LDMOS transistor. As shown in FIG. 1, the conventional LDMOS transistor includes a P type substrate 10, an N well 12 disposed in the substrate 10, a field oxide layer 14 disposed on the substrate 10, a gate structure 16 disposed on the field oxide layer 14, a P-body region 18 disposed in the substrate 10 by one side of the field oxide layer 14, an N type source region 20 disposed in the P-body region 18, and an N type drain region 22 disposed in the N well 12 by the other side of the field oxide layer 14. The P-body region 18 further includes a heavily doped P type contact region 24, and the gate structure 16 includes a gate dielectric layer 28, a gate electrode 26, and spacer structures 30.

As shown in FIG. 1, when a voltage applied to the gate electrode 26 is greater than the threshold voltage, the conventional LDMOS transistor will be turned on. In a normal condition, the signal input from the drain region 22 flows through the N well 12 under the field oxide layer 14, the channel under the gate electrode 26, and reaches the source region 20. In high voltage application, however, the input signal may directly punch through from the drain region 22 to the substrate 10 if the voltage is too high. The critical voltage that results in punch-through from the drain to the substrate is referred to as vertical breakdown voltage or drain-sub breakdown voltage.

One of the factors that affect the vertical breakdown voltage of the LDMOS transistor is the distance T between the drain region 22 and the substrate 10 (i.e. the depth of the N well 12). The larger the distance T, the larger the vertical breakdown voltage is. In addition to high vertical breakdown voltage, however, the voltage step-down ability is also required for high voltage transistors. When the LDMOS transistor is turned on, the high voltage signal input from the drain region 22 will flow to the source region 20 through the N well 12 disposed under the field oxide layer 14. In such a case, the N well 12 disposed under the field oxide layer 14 can be regarded as a resistor R (as shown in FIG. 1). When passing through the resistor R, the high voltage signal will be converted into a applicable low voltage signal.

Currently, the voltage of high voltage signals is 200-300 V, or even much higher. Accordingly, the resistance of the N well 12 has to be improved so as to convert the high voltage signal into an applicable low voltage signal. According to resistor's characteristic, the resistance of a resistor is proportional to its length, and inversely proportional to its cross-sectional area. To improve the resistance, either prolong the resistor R or reduce the cross-sectional area of the resistor R can be considered. To increase the length of the resistor R (i.e. the length of field oxide layer), however, decreases the layout density. Thus, it is preferred to increase the resistance by reducing the cross-sectional area of resistor R (i.e. the depth of the N well 12).

To reduce the depth of the N well 12 can increase the resistance of the N well 12, but it also decreases the vertical breakdown voltage. Therefore, how to improve the voltage step-down ability without influencing the vertical breakdown voltage is an issue in device design.

### SUMMARY OF THE INVENTION

It is therefore one objective of the claimed invention to provide an LDMOS transistor having improved voltage step-down ability.

It is another objective of the claimed invention to provide a method of forming an LDMOS transistor.

According to the claimed invention, an LDMOS transistor is provided. The LDMOS transistor includes a substrate having a first conductive type, a first well having a second conductive type disposed in a portion of the substrate, an isolation structure disposed in an upper portion of the first well, a drain region disposed in the first well by one side of the isolation structure, a second well having the first conductive type disposed in the substrate by the other side of the isolation structure opposite to the drain region, a source region disposed in the second well, and a deep doped region having the first conductive type disposed in the boundary between a bottom portion of the first well and the substrate. The deep doped region is heavily doped, a portion of the deep doped region is disposed in the bottom portion of the first well, and the other portion of the deep doped region is disposed in the substrate.

According to the claimed invention, a method of forming an LDMOS transistor is provided. A substrate having a first conductive type is provided, and a first well having a second conductive type is formed in the substrate. Subsequently, an isolation structure is formed in an upper portion of the first well, and a second well having the first conductive type is formed in the substrate by one side of the isolation structure. Following that, a deep doped region having the first conductive type is formed in the boundary between the first well and the substrate. The deep doped region is heavily doped, a portion of the deep doped region is disposed in the bottom portion of the first well, and the other portion of the deep doped region is disposed in the substrate.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a cross-sectional view of a conventional LDMOS transistor.

FIGS. 2-7 are schematic diagrams illustrating a method of forming an LDMOS transistor according to an embodiment of the present invention.

FIGS. 8-14 are schematic diagrams illustrating a method of forming an LDMOS transistor according to another embodiment of the present invention.

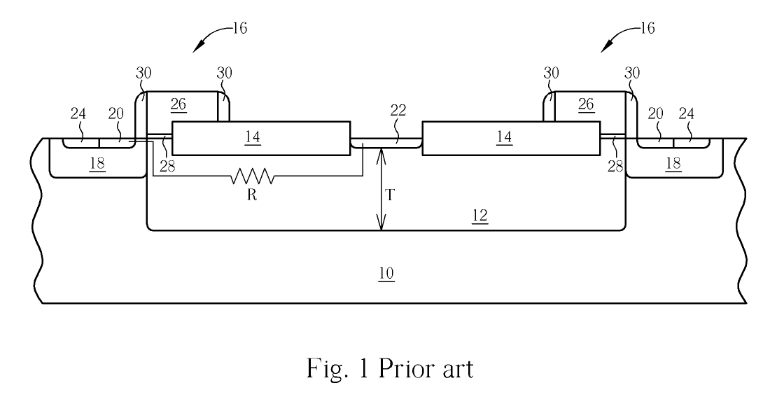

### DETAILED DESCRIPTION

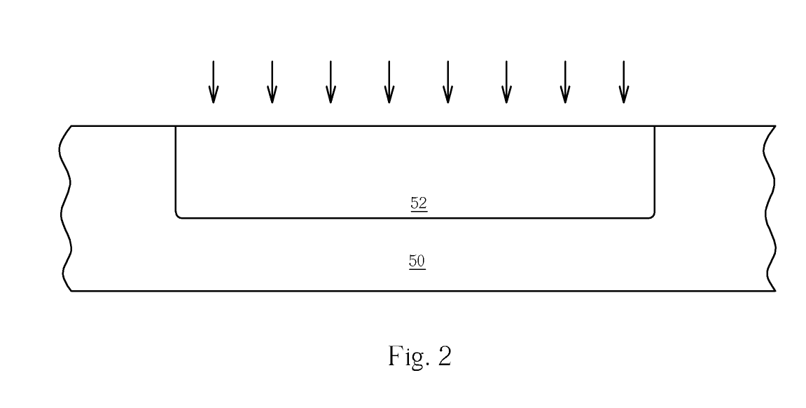

Please refer to FIGS. 2-7. FIGS. 2-7 are schematic diagrams illustrating a method of forming an LDMOS transistor according to an embodiment of the present invention. It is appreciated that in the drawings and in the following descriptions, only one single LDMOS transistor is illustrated to highlight the feature of the present invention. In addition, the first conductive type is P type, and the second conductive type is n type in this embodiment. However, the first conductive type can be N type, and the second conductive type can be P type in other embodiments where necessary.

As shown in FIG. 2, a P type substrate 50 is provided. Then, an implantation process is performed to implant N type dopants (e.g. phosphorus) into the substrate 50, and a thermal treatment is carried out to drive-in the dopants to form an N well (first well) 52 in the substrate 50.

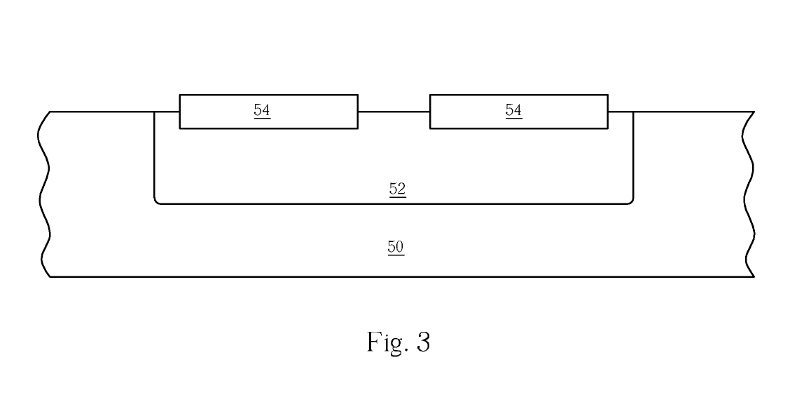

As shown in FIG. 3, a local oxidation (LOCOS) process is performed to form a field oxide layer 54 as an isolation structure in the N well 52. The field oxide layer 54 locates in the upper portion of the N well 52, and protrudes out from the surface of the substrate 50. The bottom portion of the filed oxide layer 54 is surrounded by the N well 52. The isolation structure is not limited to the field oxide layer 54, and can be other isolation structures such as shallow trench isolation (STI) structure.

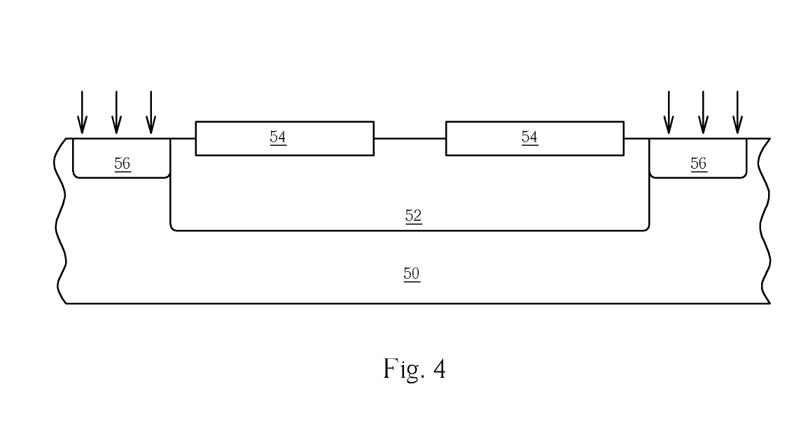

As shown in FIG. 4, an implantation process is performed to implant P type dopants (e.g. boron) into the substrate 50 disposed by one side of the field oxide layer 54, and a thermal treatment is implemented to drive-in the dopants to form a P type doped region (second well) 56. The P type doped region 56 is normally referred to as P-body region.

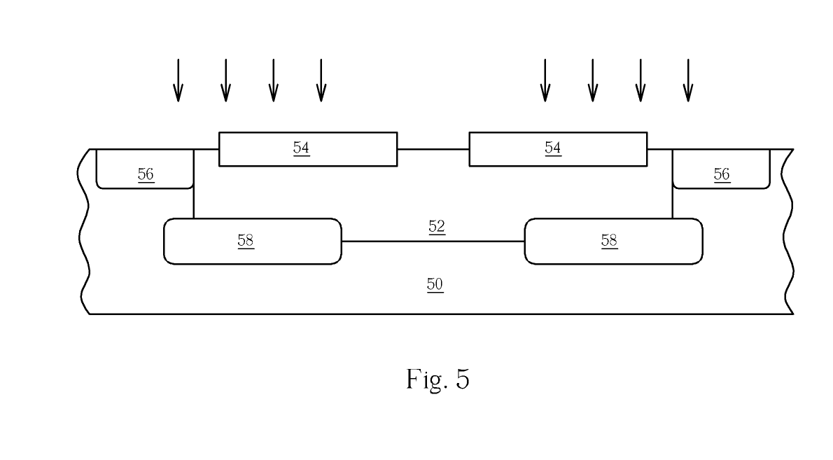

As shown in FIG. 5, another implantation process is performed to implant P type dopants into the N well 52 and the substrate 50, and a thermal treatment is carried out to form a heavily doped P type deep doped region 58 in the boundary between the N well 52 and the substrate 50. It is appreciated that the position of the P type deep doped region 58 is deeper in the substrate 50, and therefore a high energy implantation process can be used. After the thermal treatment, a portion of the P type deep doped region 58 is positioned in the bottom portion of the N well 52, and a portion of the P type deep doped region 58 is positioned in the substrate 50.

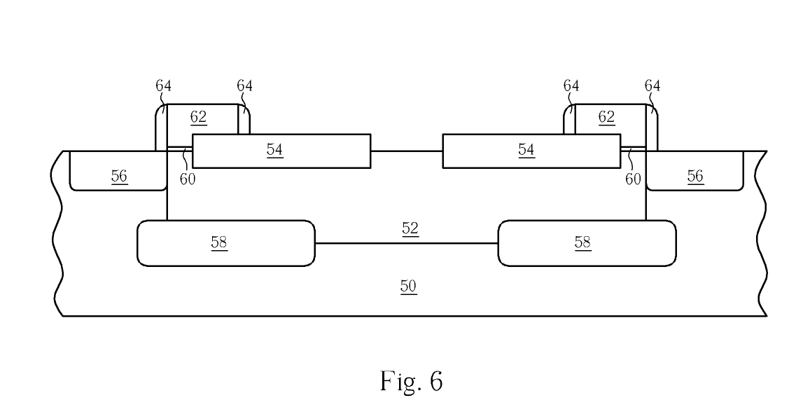

As shown in FIG. 6, an oxidation process is then performed to form a thermal oxide layer as a gate dielectric layer 60 on the surface of the substrate 50 between the field oxide layer 54 and the P type doped region 56. Subsequently, a conductive layer e.g. a polycrystalline silicon layer is deposited on the surface of the substrate 50, the gate dielectric layer 60 and the field oxide layer 54, and lithography and etching techniques are used to form a gate electrode 62 on the gate dielectric layer 60 and on a portion of the field oxide layer 54. Thereafter, spacer structures 64 are formed along both sides of the gate electrode 62. The gate dielectric layer 60, the gate electrode 62 and the spacer structures 64 form a gate structure of the LDMOS transistor.

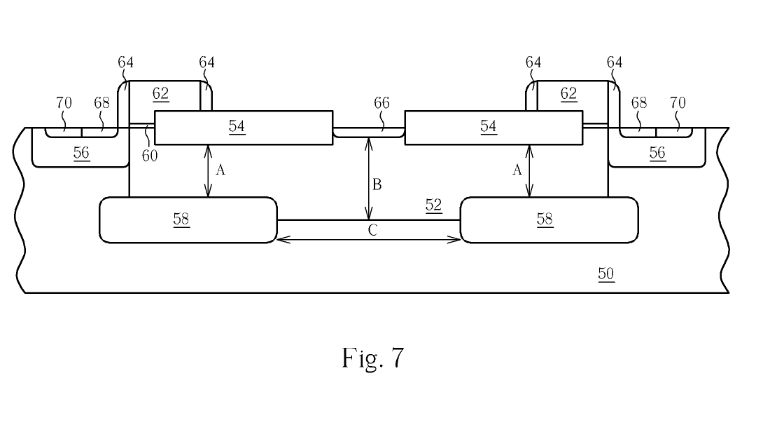

As shown in FIG. 7, an implantation process is performed to form a heavily doped N type drain region 66 in the N well 52 by one side of the field oxide layer 54, and a heavily doped N type source region 68 in the P type doped region 56 by the other side of the field oxide layer 54. In addition, another implantation process is implemented to form a heavily doped P type contact region 70, which is normally referred to as P-body contact. Subsequently, a thermal treatment is performed to drive-in the dopants in the drain region 66, the source region 68, and the P type contact region 70.

The LDMOS transistor of this embodiment disposes the P type deep doped region 58 in the boundary between the N well 52 and the substrate 50 so that the depth A of the N well 52 is reduced. By virtue of the P type deep doped region 58, when the high voltage signal flows through this path, the improved resistance increases the voltage step-down ability, converting the high voltage signal into a low voltage signal. Meanwhile, the depth B of the N well 52 positioned under the drain region 66 remains the same so that the vertical breakdown voltage is not affected. In addition, the distance C between two adjacent P type deep doped regions 58 is also maintained, making the vertical breakdown voltage unaffected.

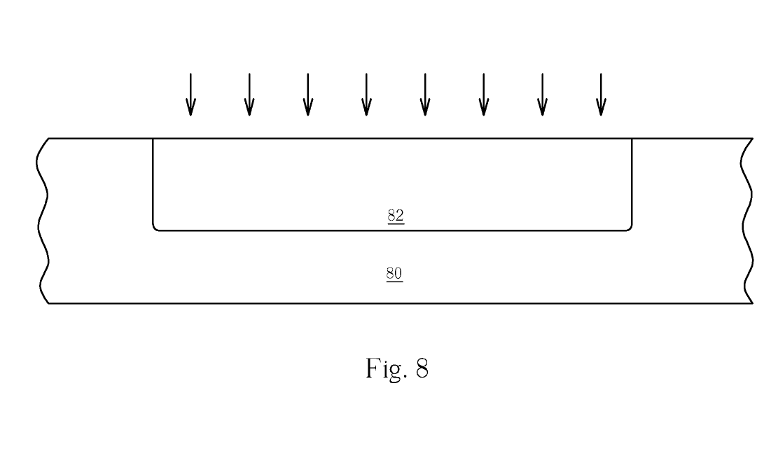

Please refer to FIGS. 8-14. FIGS. 8-14 are schematic diagrams illustrating a method of forming an LDMOS transistor according to another embodiment of the present invention. In this embodiment, the first conductive type is P type, and the second conductive type is n type. However, the first conductive type can be N type, and the second conductive type can be P type in other embodiments. As shown in FIG. 8, a P type substrate 80 is provided. Then, an implantation process and a thermal treatment are consecutively performed to form an N well (first well) 82 in the substrate 80.

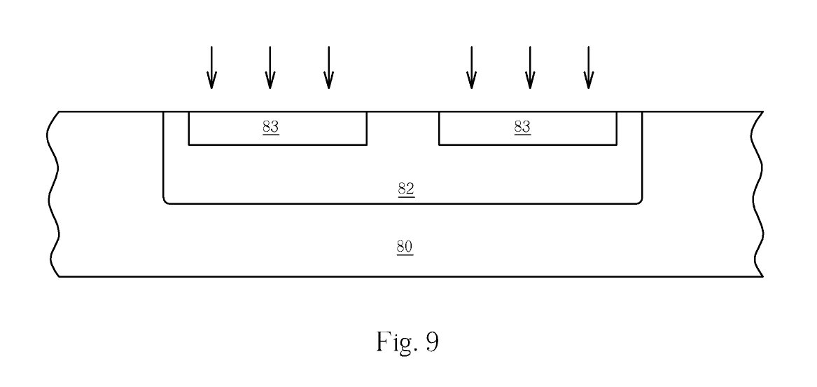

As shown in FIG. 9, P type dopants are implanted into the N well 82, and a thermal treatment is implemented to form a heavily doped P type shallow doped region 83. The P type shallow doped region 83 is also referred to as a P-top region or a drift doped region.

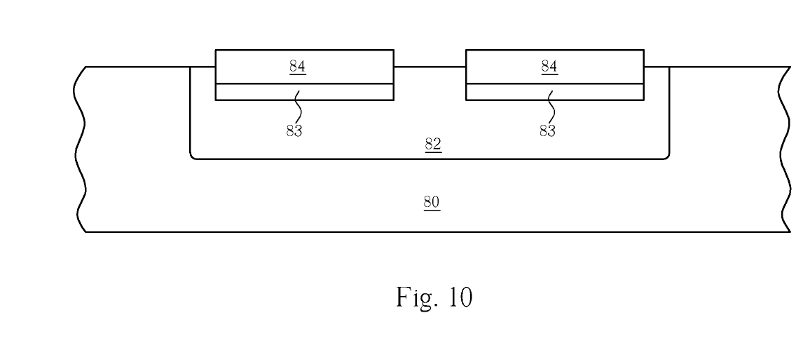

As shown in FIG. 10, a local oxidation (LOCOS) process is performed to form a field oxide layer 84 as an isolation structure in the N well 82. The field oxide layer 84 locates in the upper portion of the N well 82, and protrudes out from the surface of the substrate 80. The bottom portion of the filed oxide layer 84 is surrounded by the N well 82. The P type shallow doped region 83 is located under and corresponding to the field oxide layer 84 in this embodiment.

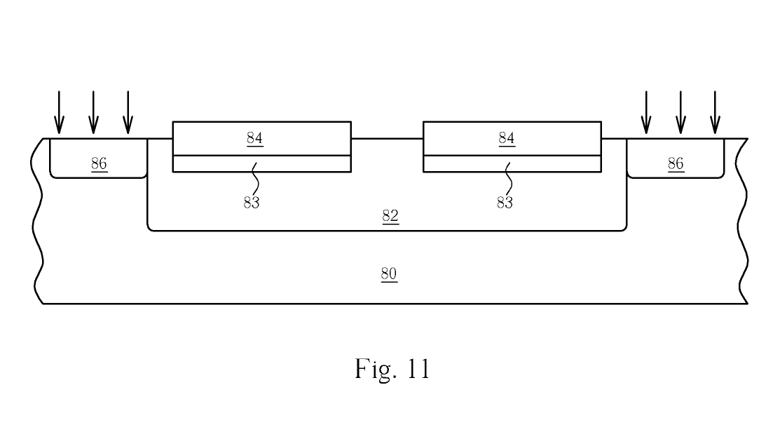

As shown in FIG. 11, an implantation process is performed to implant dopants into the substrate 80 disposed by one side of the field oxide layer 84, and a thermal treatment is implanted to drive-in the dopants to form a P type doped region (second well) 86.

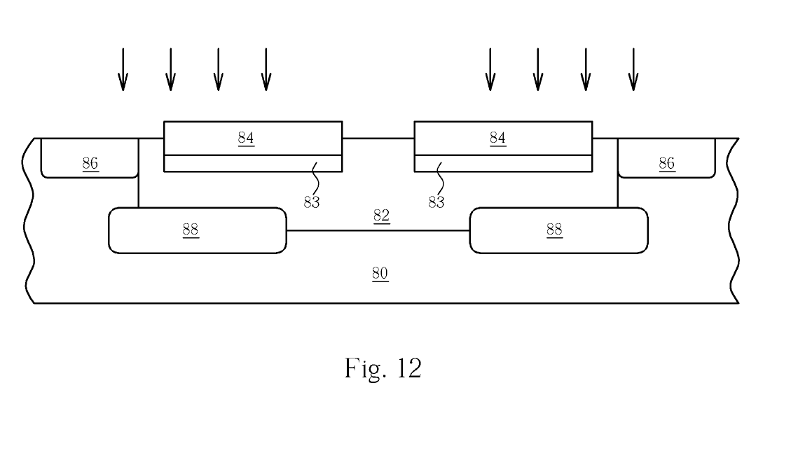

As shown in FIG. 12, another implantation process is performed to implant P type dopants into the N well 82 and the substrate 80, and a thermal treatment is performed to form a heavily doped P type deep doped region 88 in the boundary between the N well 82 and the substrate 80. It is appreciated that after the thermal treatment, a portion of the P type deep doped region 88 is positioned in the bottom portion of the N well 82, and a portion of the P type deep doped region 88 is positioned in the substrate 80.

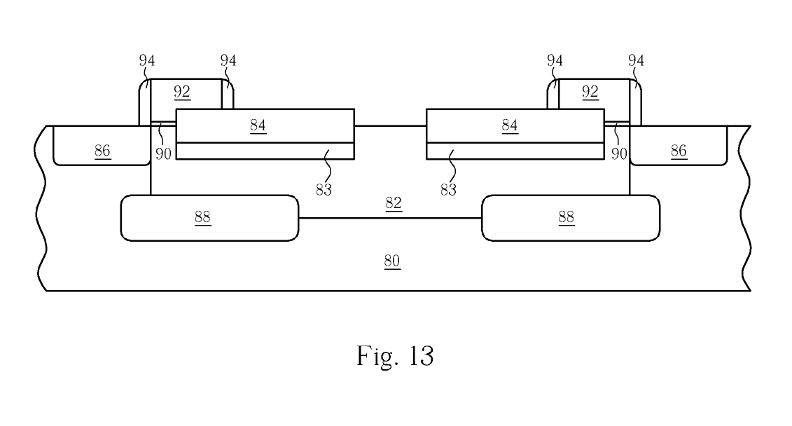

As shown in FIG. 13, an oxidation process is then performed to form a thermal oxide layer as a gate dielectric layer 90 on the surface of the substrate 80 between the field oxide layer 84 and the P type doped region 86. Subsequently, a conductive layer e.g. a polycrystalline silicon layer is deposited on the surface of the substrate 80, the gate dielectric layer 90 and the field oxide layer 84, and lithography and etching techniques are used to form a gate electrode 92 on the gate dielectric layer 90 and on a portion of the field oxide layer 84. Thereafter, spacer structures 94 are formed along both sides of the gate electrode 92. The gate dielectric layer 90, the gate electrode 92 and the spacer structures 94 form a gate structure of the LDMOS transistor.

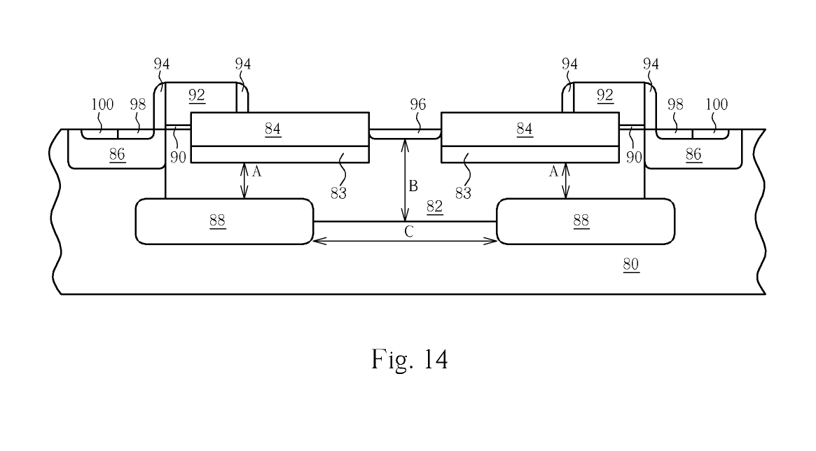

As shown in FIG. 14, an implantation process is performed to form a heavily doped N type drain region 96 in the N well 82 by one side of the field oxide layer 84, and a heavily doped N type source region 98 in the P type doped region 86 by the other side of the field oxide layer 84. In addition, another implantation process is implemented to form a heavily doped P type contact region 100. Subsequently, a thermal treatment is performed to drive-in the dopants in the drain region 96, the source region 98, and the P type contact region 100.

Different from the first embodiment of the present invention, the LDMOS transistor of this embodiment not only includes the P type deep doped region 88 between the N well 82 and the substrate 80, but also the P type shallow doped region 83 under the field oxide layer 84. Therefore, the depth A of the N well 82 is reduced by the presence of both the P type shallow doped region 83 and the P type deep doped region 88. Accordingly, when the high voltage signal flows through this path, the improved resistance increases the voltage step-down ability, converting the high voltage signal into a low voltage signal. Meanwhile, the depth B of the N well 82 positioned under the drain region 96 remains the same so that the vertical breakdown voltage is not affected. In addition, the distance C between two adjacent P type deep doped regions 88 is also maintained, making the vertical breakdown voltage unaffected.

The aforementioned embodiments are two embodiments that increase the resistance of the N well to improve the voltage step-down ability of the LDMOS transistor by either installing the P type deep doped region or installing both the P type deep doped region and the P type shallow doped region. It is appreciated that the thickness of the P type deep doped region and the P type shallow doped region can be modified if different operational voltage is required so as to output applicable low voltage signal. In addition, the P type deep doped region is formed subsequent to forming the P type shallow doped region and the P type contact region in the above embodiments, and this step order has the advantage of a reduced thermal budget and a better control of the depth and position of the P type doped region. If other process factors or requirements are taken into consideration, however, the step order of the P type deep doped region may be modified.

In summary, the present invention provide an improved voltage step-down ability by installing the P type deep doped region and the P type shallow doped region without influencing the vertical breakdown voltage. Therefore, the LDMOS transistor of the present invention is able to accept a high voltage signal up to about 600 V.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An LDMOS transistor, comprising:
a substrate having a first conductive type;
a first well having a second conductive type disposed in a portion of the substrate;
an isolation structure disposed in an upper portion of the first well;
a drain region disposed in the first well by one side of the isolation structure;
a second well having the first conductive type disposed in the substrate by the other side of the isolation structure opposite to the drain region;
a source region disposed in the second well; and
a deep doped region having the first conductive type disposed in the boundary between a bottom portion of the first well and the substrate, wherein the deep doped region is heavily doped, a portion of the deep doped region is disposed in the bottom portion of the first well, and the other portion of the deep doped region is disposed in the substrate.

2. The LDMOS transistor of claim 1, wherein a bottom portion of the isolation structure is surrounded by the first well.

3. The LDMOS transistor of claim 1, further comprising a gate dielectric layer disposed on the surface of the substrate between the isolation structure and the source region, and a gate electrode disposed on the gate dielectric layer and a portion of the isolation structure.

4. The LDMOS transistor of claim 1, further comprising a doped region having the first conductive disposed in the substrate and encompassing the source region, and a contact region disposed in the doped region.

5. The LDMOS transistor of claim 1, further comprising a shallow doped region having the first conductive type disposed in the first well under the isolation structure.

6. The LDMOS transistor of claim 5, wherein the shallow doped region is heavily doped.

7. The LDMOS transistor of claim 5, wherein the shallow doped region is substantially corresponding to the isolation structure disposed thereon.

8. The LDMOS transistor of claim 1, where the first conductive type is P type, and the second conductive type is N type.

9. The LDMOS transistor of claim 1, wherein the isolation structure comprising a field oxide layer.

10. A method of forming an LDMOS transistor, comprising:
providing a substrate having a first conductive type;
forming a first well having a second conductive type in the substrate;
forming an isolation structure in an upper portion of the first well;
forming a second well having the first conductive type in the substrate by one side of the isolation structure; and
forming a deep doped region having the first conductive type in the boundary between the first well and the substrate, wherein the deep doped region is heavily doped, a portion of the deep doped region is disposed in the bottom portion of the first well, and the other portion of the deep doped region is disposed in the substrate.

11. The method of claim 10, further comprising forming a gate electrode on the isolation structure subsequent to forming the deep doped region.

12. The method of claim 11, further comprising forming a drain region in the first well, and a source region in the second well.

13. The method of claim 10, further comprising forming a shallow doped region having the first conductive type in the first well.

14. The method of claim 13, wherein the shallow doped region is heavily doped.

15. The method of claim 10, wherein the first conductive type is P type, and the second conductive type is N type.
